(19) United States
(12) Patent Application Publication
(10) Pub. No.: US 2007/0284764 A1
(43) Pub. Date: Dec. 13, 2007

(54) Sensing mechanism for crystal orientation indication mark of semiconductor wafer

(75) Inventor: Kazuma Sekiya, Tokyo (JP)

Correspondence Address: BRINKS HOFER GILSON & LIONE, P.O. BOX 10395, CHICAGO, IL, 60610, US

(73) Assignee: DISCO CORPORATION

(21) Appl. No.: 11/810,938

(22) Filed: Jun. 6, 2007

(30) Foreign Application Priority Data
Jun. 9, 2006 (JP) 2006-160988

(51) Int. Cl. G01B 11/00; H01L 23/544

(52) U.S. Cl. 257/797; 356/399

(57) ABSTRACT

A sensing mechanism for crystal orientation indication mark of semiconductor wafer is provided. The semiconductor wafer includes: a device region formed on a surface of the semiconductor wafer, plural devices are formed or are to be formed on the surface; a circular peripheral extra region formed around the device region; a chamfered portion formed at a peripheral edge portion of the peripheral extra region; a flat surface as a mark indicating a crystal orientation of the semiconductor wafer. The mark is positioned within a region of the chamfered portion and is perpendicular to a surface direction of the semiconductor wafer. The sensing mechanism includes: an optical sensor having an optical axis parallel to the surface direction of the semiconductor wafer; and a rotatable holding table for holding the semiconductor wafer. The flat surface is sensed by the sensing mechanism.

This application claims priority under 35 U.S.C. §119 to Japanese Patent Application No. JP2006-160988 filed Jun. 9, 2006, the entire content of which is hereby incorporated by reference.

### BACKGROUND OF THE INVENTION

1. Field of the Invention

The present invention relates to a mechanism for sensing an indication mark which is provided on a side surface of a semiconductor wafer and indicates a crystal orientation thereof. In particular, the present invention relates to a mechanism for sensing a crystal orientation indication mark which is a flat surface indicating a crystal orientation of a semiconductor wafer, the indication mark positioned within a region of a curved chamfered portion which is formed at a peripheral edge portion of a semiconductor wafer.

2. Description of Related Art

A single crystal semiconductor wafer (hereinafter referred to simply as “wafer”) composed of Si or the like has semiconductor devices formed on a surface thereof. In order to thin this wafer, a method is disclosed in which only rear surface of the wafer corresponding to a device region is processed to have a necessary thickness and a peripheral extra region is thicker than the device region (see Japanese Unexamined Patent Application Publications Nos. 2004-281551 and 2005-123425). In the conventional method disclosed in Japanese Unexamined Patent Application Publications Nos. 2004-281551 and 2005-123425, a wafer having a crystal orientation indication mark (for example, a triangular notch or an orientation flat) is used to indicate a crystal orientation thereof. Next, semiconductor devices are formed on a surface thereof so as to be adjusted to the crystal orientation, and only rear surface of the wafer which corresponds to a device region is thinned. In this case, since the notch and the orientation flat are cut into the wafer toward a radial center direction of the wafer, in order to sufficiently ensure a width of a peripheral extra region at an overall circumference of the wafer, this width should be wider in accordance therewith. Due to this, in the wafer having a notch or an orientation flat, the width of the peripheral extra region is required in surplus for formation of the notch or the orientation flat. Thus, areas of the device regions decrease, the number of device chips produced from one wafer decreases, and the production cost becomes high.

The inventor has proposed the following indication mark indicating a crystal orientation of a wafer. That is, the indication mark is a flat surface formed at a peripheral edge portion of a peripheral extra region of the wafer. The indication mark is perpendicular to a surface direction of the wafer, and it is positioned within a region of convex chamfered portion formed at the peripheral edge portion.

When devices are formed on a surface of a wafer, a crystal orientation indication mark (for example, an orientation flat) is sensed by a sensor, and a device circuit is lithographed so as to be adjusted to a crystal orientation of the wafer. In a wafer having a conventional notch or a conventional orientation flat, the wafer is coaxially chucked by a rotatable chuck table, and the crystal orientation indication mark is sensed by a photosensor disposed across an edge portion of the wafer. This photosensor is equipped with a projector and a photoreceiver. In this photosensor, light projected from the projector passes through an air gap of the crystal orientation indication mark, and it is received by the photoreceiver. Thus, this photosensor senses the crystal orientation indication mark.

However, in a wafer having the crystal orientation indication mark which has previously proposed by the inventor, since recessed amount of the crystal orientation indication mark from a peripheral circle of the wafer is small, light amount change is small when light is projected and received from a surface and a rear surface of the wafer. Due to this, it is difficult to sense the crystal orientation indication mark.

### SUMMARY OF THE INVENTION

Therefore, an object of the present invention is to provide a sensing mechanism for a crystal orientation indication mark of a semiconductor wafer, wherein the sensing mechanism can reliably sense the crystal orientation indication mark even when the semiconductor wafer has a small recessed amount of the crystal orientation indication mark from a peripheral circle of the semiconductor wafer.

According to one aspect of the present invention, a sensing mechanism for crystal orientation indication mark of semiconductor wafer is provided. The semiconductor wafer includes: a device region formed on a surface of the semiconductor wafer, plural devices being formed or to be formed on the surface; a circular peripheral extra region formed around the device region; a chamfered portion formed at a peripheral edge portion of the peripheral extra region; a flat surface as a mark indicating a crystal orientation of the semiconductor wafer. The mark is positioned within a region of the chamfered portion and is perpendicular to a surface direction of the semiconductor wafer. The sensing mechanism includes: an optical sensor having an optical axis parallel to the surface direction of the semiconductor wafer; and a rotatable holding table for holding the semiconductor wafer. The flat surface is sensed by the sensing mechanism.

In the sensing mechanism of the present invention, while the semiconductor wafer (hereinafter referred to simply as “wafer”) is held and rotated by the holding table, light is projected from the optical sensor to the side surface of the wafer. The light is reflected by the flat surface when the optical axis of the optical sensor is perpendicular to the flat surface. The reflected light is received by the optical sensor, so that the flat surface is sensed. Therefore, even when recessed amount of the mark from a peripheral circle of the wafer is small in the wafer, the flat surface which is the crystal orientation indication mark (hereinafter referred to simply as “mark”) can be reliably sensed.

When the mark is sensed by the sensing mechanism of the present invention, the holding table may be immediately stopped. Alternatively, after the mark is sensed by the sensing mechanism of the present invention, the holding table may be rotated by predetermined angles, and it may be stopped thereat. In order that the sensing mechanism perform this action, for example, the sensing mechanism may include: an encoder provided at a rotational shaft of the holding table; a storage device for storing an encoder value of the rotational shaft which is obtained by the encoder, the rotational shaft positioned at a position at which the optical sensor responds to reflection light; and a rotating device for rotating the holding table from the responded position of the rotational shaft to a predetermined position of the rotational shaft and for stopping the holding table at the predetermined position.

When the mark is sensed and the wafer is positioned at one direction, the wafer may be carried from the holding table to one mechanism (for example, a device forming mechanism) in a condition that the direction of the wafer is maintained. In the device forming mechanism, the wafer may be positioned at a position corresponding to the crystal orientation, and devices may be formed thereat. Several tens of processes may be necessary for the formation of the devices. Therefore, the sensing mechanism of the present invention may be disposed every process, and sensing of the mark and positioning of the wafer may be performed. Alternatively, after the forming of the devices, the wafer may be thinned, and the wafer may be applied onto a dicing tape. When directions of a dicing frame, which is applied around the dicing tape, and the wafer are determined, sensing of the mark may be performed. After the wafer is applied onto the dicing tape, positioning of the wafer may be performed by using a notch of the dicing frame for positioning, and dicing may be performed with reference to the position.

The peripheral edge portion of the present invention may be a curved portion which is formed at a peripheral side of the wafer and which has a very narrow width. When a chamfered portion, which is chamfered to have a circular arc cross section from a surface side of the wafer to a rear surface side thereof, is defined as a peripheral edge portion, the mark may be formed within a region of the chamfered portion. The mark may be elliptic by forming of the flat surface at the chamfered portion. An outer shape edge of the mark may be chamfered so that an angular portion is removed. In this feature of the present invention, since breakage, cracking, or generation of dust may not easily occur in the wafer, this feature may be desirable. Cut amount of the mark, which indicates the crystal orientation, to an inside of a radial direction of the wafer is desirably as small as possible such that the flat surface can have a certain degree of area. For example, the flat surface is desirably formed within 0.3 mm from an outermost peripheral edge of the wafer to an inside of radial direction thereof.

The wafer of the present invention may project to have a rib shape on the rear surface of the peripheral extra region. Thus, for example, the rib shape is set such that the peripheral extra region is thicker than the device region. Since the above mark is formed on the wafer in this manner, width of the thick portion, which corresponds to the peripheral extra region having the rib shape, can be as narrow as possible. As a result, the device region can be large and the number of the devices can be increased.

In the mark sensing mechanism of the present invention, since the mark sensing mechanism has an optical sensor having an optical axis parallel to the surface direction of the semiconductor wafer and a rotatable holding table for holding the semiconductor wafer, the mark can be reliably sensed even when the recessed amount of the mark from the peripheral circle of the wafer is small.

### BRIEF DESCRIPTION OF THE DRAWINGS

FIGS. 1A to 1C are a plan view, a side view, and a perspective view which show a semiconductor wafer processed in one embodiment according to the present invention.

FIGS. 2A and 2B are enlarged views which show a semiconductor wafer processed in one embodiment, and FIG. 2A is a plan view showing a portion of the semiconductor wafer and FIG. 2B is a perspective view showing the semiconductor wafer.

FIGS. 3A and 3B show a semiconductor wafer processed in one embodiment, and FIG. 3A is a cross sectional view showing a chamfered portion of the semiconductor wafer other than that of a portion having a mark formed thereon, and FIG. 3B is a cross sectional view showing a chamfered portion having the portion of the semiconductor wafer which has a mark formed thereon.

FIG. 4 is a perspective view showing a grinding apparatus.

FIG. 5 is a side view showing a grinding apparatus.

FIGS. 6A and 6B are a plan view and a cross sectional view which show a semiconductor wafer in which a peripheral extra region is formed at a thick portion.

FIG. 7 is a plan view showing a wafer for comparing width difference of thick portion between one embodiment of the present invention and a comparative case that a conventional notch or a conventional orientation flat is formed to a semiconductor wafer processed in one embodiment.

FIG. 8 is a side view showing a sensing mechanism for a crystal orientation indication mark of semiconductor wafer of one embodiment according to the present invention.

FIG. 9 is a perspective view showing a sensing mechanism for a crystal orientation indication mark of semiconductor wafer of one embodiment according to the present invention.

### DETAILED DESCRIPTION OF THE PREFERRED EMBODIMENTS

### 1. Structure of Wafer

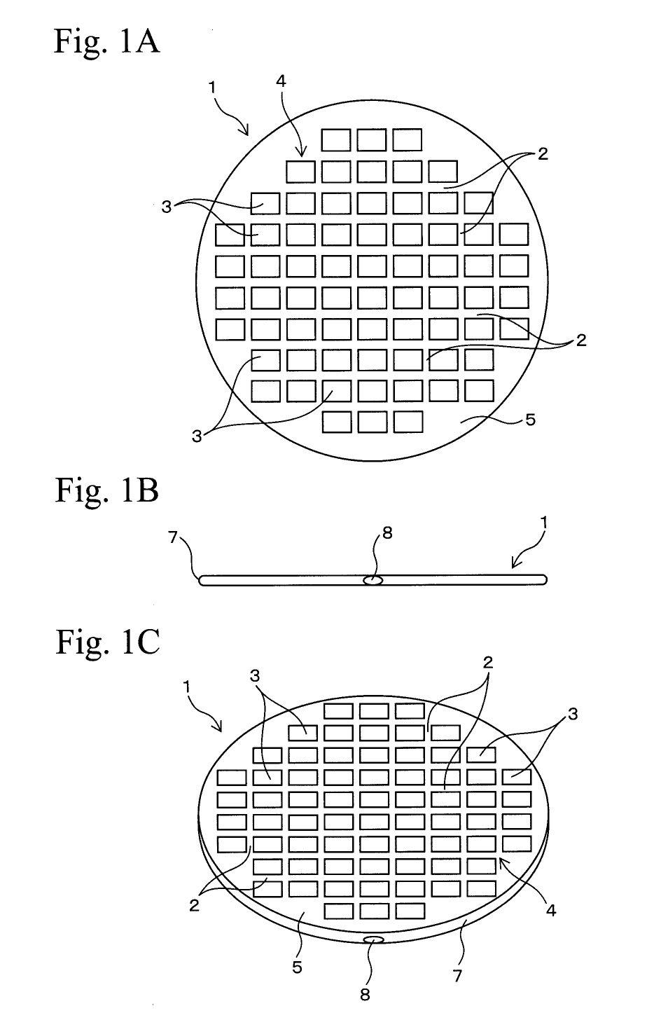

One embodiment according to the present invention will be explained hereinafter with reference to the drawings. FIGS. 1A to 1C show a semiconductor wafer (hereinafter referred to simply as a “wafer”) 1 which is composed of a single crystal silicon or the like and which is processed in one embodiment according to the present invention. For example, the wafer 1, which is disk-shaped and has a crystal orientation, has a thickness of about 600 μm. Grid-like predetermined division lines 2 are formed on a surface of the wafer 1, and plural rectangular semiconductor chips (devices) 3 are defined by the predetermined division lines 2 on the surface of the wafer 1. Electronic circuits are formed on surfaces of the semiconductor chips 3. The plural semiconductor chips 3 are formed on a device region 4 which is almost circular so as to be concentric with the wafer 1. A ring-shaped peripheral extra region 5 is formed around the device forming region 4.

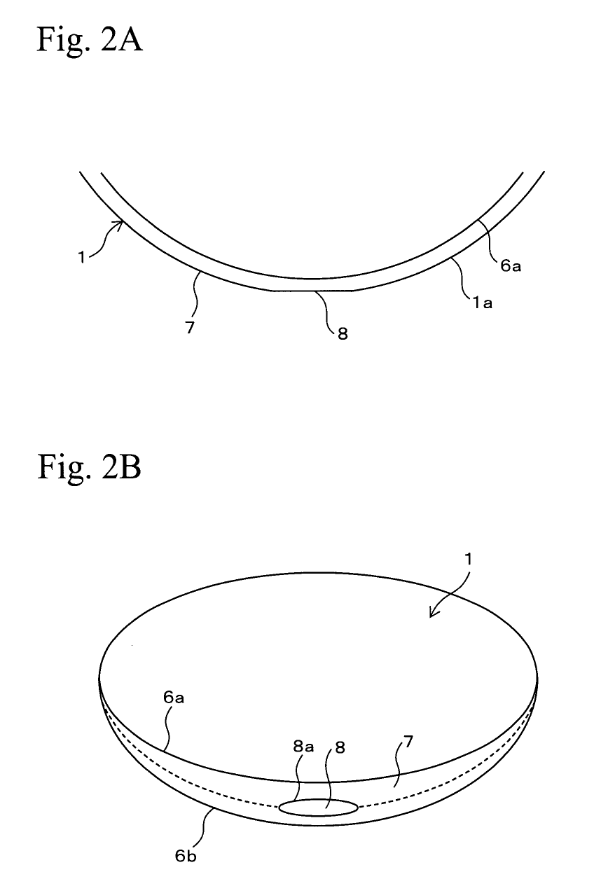

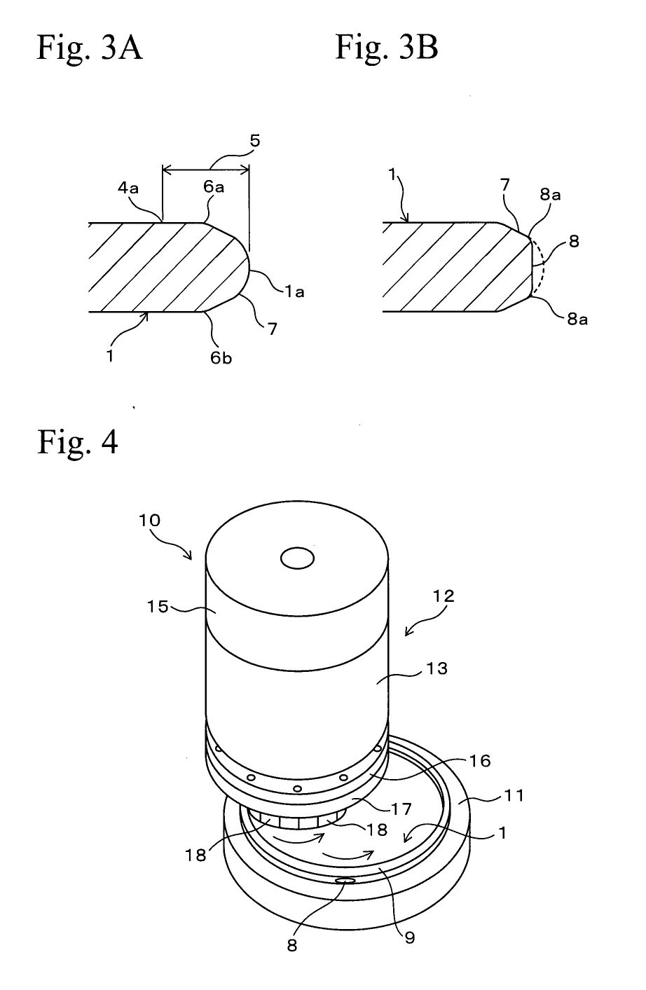

As shown in FIGS. 2A to 3B, a peripheral edge portion of the wafer 1 is chamfered from a surface side of the wafer 1 to a rear surface side thereof. Thus, a chamfered portion 7 having a circular arc cross section is formed between a surface edge 6a and a rear surface edge 6b which are complete round. Since the chamfered portion 7 is formed, breakage, cracking, or generation of dust, which may be caused by sudden impacts to the wafer 1, can be prevented. As shown in FIG. 3A, the peripheral extra region 5 is a ring-shaped region between a device region peripheral edge 4a and an outermost peripheral edge 1a of the wafer 1, the device region peripheral edge 4a being positioned a predetermined distance from the surface edge 6a to an inside of radial direction. As shown in FIGS. 2A, 2B, and 3B, a crystal orientation indication mark 8 is formed at a predetermined position on the chamfered portion 7 by cutting an inner portion from the outermost peripheral edge 1a. The above position of the mark 8 is set such that a line which connects a center of the wafer 1 and the mark 8 is parallel or perpendicular to the grid-like predetermined division lines 2, and the mark 8 is used for indicating the crystal orientation of the wafer 1.

As shown in FIG. 3B, the mark 8 is a flat surface perpendicular to a surface direction (which is parallel to the surface and the rear surface) of the wafer 1. As shown in FIG. 2B, the mark 8 has an elliptic shape having a major axis parallel to a tangential line of the wafer 1. As shown in FIG. 3B, the mark 8 is formed at a region of the chamfered portion 7. For example, when the wafer 1 has an outer diameter of 200 mm and the chamfered portion 7 has a width of 0.5 mm which extends from the outermost peripheral edge 1a in a radial direction, the mark 8 is formed within 0.3 mm from the outermost peripheral edge 1a to an inside of radial direction. In this case, the mark 8 has a major axis of about 22 mm. The mark 8 has an outer shape edge 8a which forms the elliptic shape of the mark 8. Since the outer shape edge 8a is chamfered in a circular arc cross section and is not angular, breakage, cracking, or generation of dust does not easily occur.

The mark 8 is formed as follows. A columnar ingot is obtained as a semiconductor material composed of silicon. The ingot is cut into round slices so that a wafer 1 is obtained. That is, a flat surface is formed at a predetermined position of a circumferential direction on a circumferential surface of the ingot before slicing. In this case, at this position of the circumferential direction, a mark 8, which corresponds to the crystal orientation of the wafer 1, will be formed. The flat surface extends to be strip-shaped in an axial direction, and it has a predetermined width (for example, 22 mm as describe above). Next, the ingot is cut into round slices so that the wafer 1 is obtained. A peripheral edge portion of the wafer 1 is chamfered. As a result, the flat surface, which was first formed to be strip-shaped, remains as an elliptic mark 8.

In the wafer 1 processed in the embodiment, the mark 8 indicating the crystal orientation is the flat surface formed at the chamfered portion 7 which is the peripheral edge portion. Due to this, the peripheral extra region 5 has a width which can be as small as possible without being influenced by cut amount of the mark 8 to an inside of radial direction, and the device region 4 can be obtained as large as possible. As a result, in comparison with the conventional crystal orientation indication mark (for example, a notch or an orientation flat), the number of semiconductor chips defined in the device region 4 can be increased.

Next, the device region 4 of the wafer 1 is greatly thinned to have a thickness (for example, about 200 to 100 μm or about 50 μm), so that a rib-shaped thick portion for reinforcing is formed on a rear surface of the peripheral extra region 5 so as to project thereon. This wafer 1 will be explained hereinafter. In order to produce this wafer 1, after a protective tape for protecting the electronic circuits of the semiconductor chips 3 is applied onto the surface of the wafer 1, the rear surface of the wafer 1 which corresponds to the device region 4 of the wafer 1 is ground, so that the device region 4 is thinned to have the above thickness.

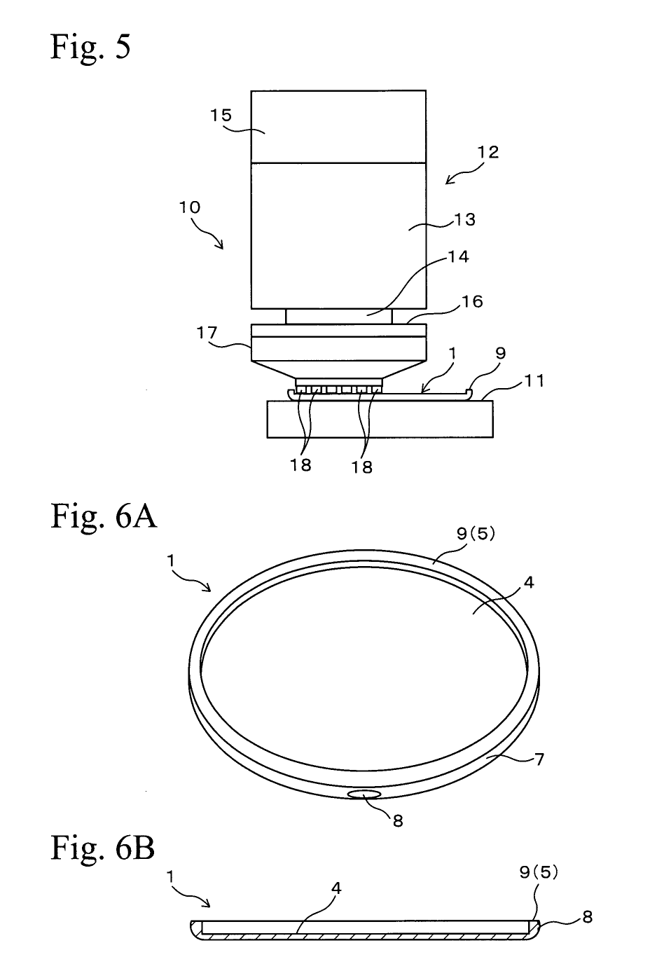

FIGS. 4 and 5 show a grinding apparatus 10 which is desirably used for grinding the wafer 1. The grinding apparatus 10 is equipped with a chuck table 11 and a grinding unit 12. The chuck table 11 is vacuum chuck type one which rotates. The chuck table 11 is disk-shaped and is larger than the wafer 1. The chuck table 11 chucks and holds the wafer 1 on an upper surface thereof by air suction. The chuck table 11 is rotated around an axis, which is positioned at a center thereof, by a motor (not shown in the drawings).

The grinding unit 12 is equipped with a cylindrical housing 13, a spindle 14, a motor 15, a flange 16, a cup wheel 17, and plural grinding stones 18. The spindle 14 is provided in the housing 13. The cup wheel 17 is secured at a leading end of the spindle 14 via the flange 16. The grinding stones 18 are secured at an overall circumference of peripheral portion of lower surface of the cup wheel 17 so as to be annularly arranged. In this grinding unit 12, the spindle 14 is rotated by the motor 15, the cup wheel 17 is rotated, and the grinding stones 18 grind a work. An outer diameter of circular grinding locus formed by the grinding stones 18 is nearly equal to a radius of the device region 4 of the wafer 1.

The grinding unit 12 is offset with respect to the chuck table 11. As shown in FIG. 5 in detail, this relative position is set such that an almost center portion of an edge thickness (radial direction length) of an edge of a grinding stone 18, which is positioned at the innermost side of the chuck table 11 among the grinding stones 18, is positioned on a vertical line which passes through the center of the chuck table 11.

The wafer 1 is held on the chuck table 11 such that the surface, which has the protective tape 11 applied thereon, faces the upper surface of the chuck table 11 and the center of the wafer 1 corresponds to the rotational center of the chuck table 11. Next, while the cup wheel 17 is rotated, the grinding unit 12 is moved downwardly, the grinding stones 18 are pressed onto the exposed rear surface of the wafer 1, and the chuck table 11 is rotated. Thus, a portion of the rear surface corresponding to the device region 4 is thinned by grinding. As a result, as shown in FIGS. 6A and 6B, the wafer 1 has a recessed cross section such that a ring-shaped thick portion 9 having an initial thickness is formed at a portion which corresponds to the peripheral extra region 5 around the device region 4 and it projects on the rear surface of the wafer 1.

The thick portion 9 formed in the above manner is subjected to necessary processing, and it is finally cut and removed by using an appropriate device. The thick portion 9 has a width which is appropriately set based on the diameter of the wafer 1, the thickness of the thick portion 9, and the processed condition of the rear surface. For example, when the wafer 1 has a diameter of 200 mm and a thickness of 725 μm, the wafer 1 desirably has a width of 2 mm. Alternatively, when the thick portion 9 is formed after the wafer 1 is thinned to have a thickness of about 300 μm, the wafer 1 desirably has a width of about 3 mm.

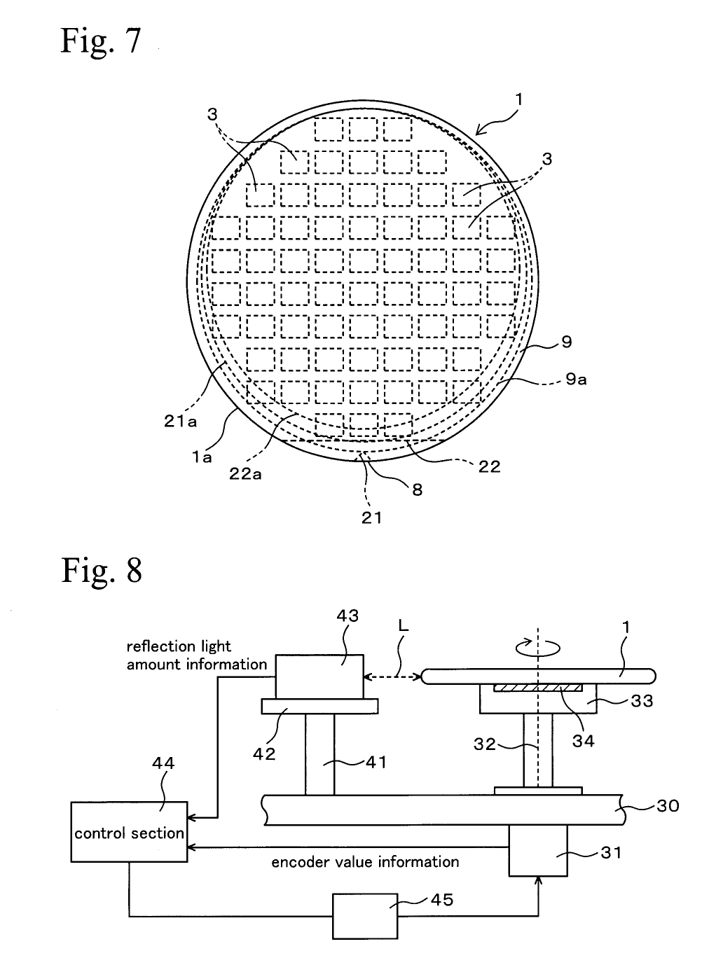

FIG. 7 is a plan view showing a width difference of thick portion between a case using a mark 8 of the embodiment of the present invention and a comparative case using a conventional notch 21 and a conventional orientation flat 22. The mark 8, the notch 21, or the orientation flat 22 is formed to the wafer 1 having the thick portion 9 formed in the above manner. In FIG. 7, reference numeral 8 denotes a portion at which the mark is formed. An inner diameter of the thick portion 9 is defined by a broken line 9a in the case using the mark 8, and the device region 4 is disposed inside the broken line 9a. When the diameter of the wafer 1 is 200 mm, the position of the inner diameter 9a is set 2 to 3 mm from the outermost peripheral edge 1a.

On the other hand, when the notch 21 is formed to the wafer 1 having the same diameter, the position of deepest portion of the notch 21 is set about 1 mm from the outermost peripheral edge 1a. Thus, a width, which is an inner diameter 21 a corresponding to the notch 21 of the thick portion, is 3 to 4 mm by providing a margin of 2 to 3 mm thereto. When the orientation flat 22 is formed to the wafer 1 having the same diameter, maximal cut amount is about 2.2 mm from the outermost peripheral edge 1a. Thus, a width, which is an inner diameter 22a corresponding to the orientation flat 22 of the thick portion, is 5.2 to 6.2 mm by providing a margin of 2 to 3 mm thereto.

In comparison between the case using the mark 8 and the case using the notch or the orientation flat, since the mark 8 of the wafer 1 processed in the embodiment is formed within the chamfered portion 7 and cut amount of the mark 8 to the inside of the radial direction is very small, the width of the thick portion 9 can be narrow. As a result, the device region 4 can be large and the produced number of the semiconductor chips 3 can be increased.

### 2. Construction of Mark Sensing Mechanism

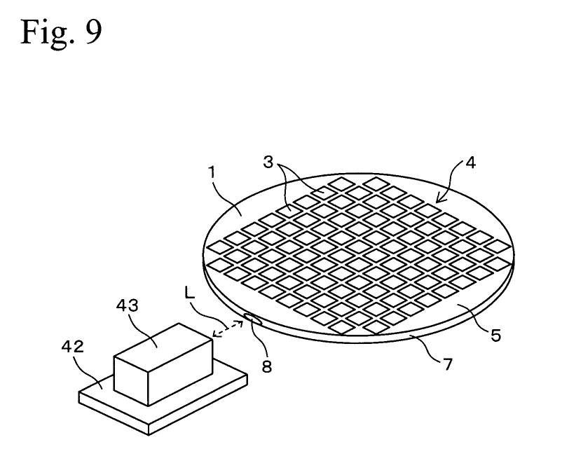

Next, a mark sensing mechanism of the embodiment according to the present invention will be explained with reference to FIGS. 8 and 9. In FIG. 8, reference numeral 30 denotes a base frame of the mark sensing mechanism. For example, a frame of a device forming apparatus is used as the base frame 30. An AC servo motor 31 having an encoder provided therein is provided to the base frame 30. A rotational table 33 is provided to an output shaft of the AC servo motor 31 via a table post 32. A porous portion 34 is disposed on an upper surface of the rotational table 33. A hole communicating the porous portion 34 is formed in the table post 32 and the rotational table 33. A vacuum suction apparatus (not shown in the drawings) is connected to the hole, so that the wafer 1 is chucked on the porous portion 34.

A bracket 42 is provided to the base frame 30 via a sensor post 41. A photosensor 43 is provided on the bracket 42. The photosensor 43 is equipped with a projector and a photoreceiver. An optical axis L of them faces a side surface of the wafer 1 and has a height corresponding to a center of thickness direction of the wafer 1. In FIG. 8, reference numerals 44 and 45 denote a control section and a motor driver. The control section 44 controls the action of the mark sensing mechanism. Light projected from the projector of the photosensor 43 reflects on the side surface of the wafer 1. Reflection amount of the reflection light received by the photoreceiver is maximal when the mark 8 reaches so as to face a front surface of the photosensor 43 by rotating of the wafer 1. The control section 44 inputs reflection light amount information corresponding to the amount of the light received from the photosensor 43, and it controls the motor driver 45 based on the reflection light amount information. An encoder value information from the encoder of the AC servo motor 31 is input into the control section 44.

### 3. Action of Mark Sensing Mechanism

Next, the action of the above constructed mark sensing mechanism will be explained hereinafter. First, the wafer 1 is positioned such that a center of the wafer 1 corresponds to a rotational center of the rotational table 33, and it is mounted onto the rotational table 33. Since the chucking of the rotational table 33 has already started at this time, the wafer 1 is chucked by the rotational table 33. Next, the AC servo motor 31 rotates, and the direction of the rotational table 33 is input into the control section 44 as an encoder value. The photosensor 43 projects light from the projector to the side surface of the wafer 1. When the mark 8 reaches so as to face the front surface of the photosensor, reflection amount of the reflection light received by the photoreceiver is maximal. That is, reflection light amount information input from the photosensor 43 into the control section 44 is maximal, and the control section 44 stores the direction of the rotational table 33 as an encoder value, the rotational table 33 positioned when the reflection light amount information is maximal.

After the amount of the reflection light amount information is maximal, the control section 44 stops the rotational table 33 at a predetermined direction. For example, the stop of the rotational table 33 can be performed at the moment that the reflection light amount information becomes maximal. Alternatively, the rotational table 33 can be rotated by predetermined angles from a position of the rotational table 33 when the reflection light amount information becomes maximal, and it can stop thereat. In these features, the direction of the wafer 1 is constant, and the wafer 1 is transferred to the following process in a condition that the direction of the wafer 1 is maintained.

In the above mark sensing mechanism, since the light is projected from the photosensor 43 to the side surface of the wafer 1 and the mark 8 is sensed by the reflection light, the mark 8 can be reliably sensed even when the recessed amount of the mark 8 from the peripheral circle of the wafer 1 is small.

What is claimed is:

1. A sensing mechanism for a crystal orientation indication mark of a semiconductor wafer, wherein
the semiconductor wafer comprising:
a device region formed on a surface of the semiconductor wafer, plural devices being formed or to be formed on the surface;
a circular peripheral extra region formed around the device region;
a chamfered portion formed at a peripheral edge portion of the peripheral extra region;
a flat surface as a mark indicating a crystal orientation of the semiconductor wafer, the mark being positioned within a region of the chamfered portion and being perpendicular to a surface direction of the semiconductor wafer, wherein
the sensing mechanism comprising:
an optical sensor having an optical axis parallel to the surface direction of the semiconductor wafer; and
a rotatable holding table for holding the semiconductor wafer, wherein
the flat surface is sensed by the sensing mechanism.

2. A sensing mechanism for a crystal orientation indication mark of a semiconductor wafer, according to claim 1, wherein
the sensing mechanism comprising:
an encoder provided at a rotational shaft of the holding table;
a storage device for storing an encoder value of the rotational shaft which is obtained by the encoder, the rotational shaft being positioned at a position at which the optical sensor responds to reflection light; and
a rotating device for rotating the holding table from the responded position of the rotational shaft to a predetermined position of the rotational shaft and for stopping the holding table at the predetermined position.
